(19) United States
(12) Patent Application Publication
(10) Pub. No.: US 2012/0000509 A1
(43) Pub. Date: Jan. 5, 2012

(54) MULTI-DIRECTIONAL SOLAR ENERGY COLLECTOR SYSTEM

(75) Inventor: Cheng-Hong Chen, Hsinchu (TW)

(73) Assignee: Epistar Corporation, Hsinchu (TW)

(21) Appl. No.: 13/175,690

(22) Filed: Jul. 1, 2011

(30) Foreign Application Priority Data
Jul. 2, 2010 (TW) 099121951

(51) Int. Cl. H01L 31/052; G02B 17/00; H01L 31/0232

(52) U.S. Cl. 136/246; 136/259; 359/726

(57) ABSTRACT

The present disclosure provides a multi-directional solar energy collector system. It comprises a light concentration device which includes one or plural light concentration lens and one or plural chambers. By means of the light concentration device, the incoming light can be concentrated once or multiple time, then is guided to the solar cell. The system is able to collect incoming light from various directions without consuming additional power.

### RELATED APPLICATION

This application claims the right of priority based on TW application Ser. No. 099121951 filed on. July 02, 2010; the contents of which are incorporated herein by reference in their entirety.

### BACKGROUND

1. Technical Field

The present disclosure disclosed a solar energy collector, especially related to a solar energy collector which receives incident lights from multiple directions.

2. Description of the Related Art

Solar cell coverts solar energy to electric power and becomes a renewable energy source. Considering the environmental factor, solar energy is the most popular energy source among others. In order to fully utilize energy from the sun, ways to collect the incident solar lights and improve the overall conversion efficiency are typically a key focus. A conventional way to help collect incident solar lights is to increase the exposure under the sun. FIG. 1 illustrates a common solar cell with a tracker. It utilizes photovoltaic panels 03 to collect the incoming light 02. As the overall energy generated by the incident light 01 is restrained by the angle between the incident light 01 and the photovoltaic panel 03, a driver 04 is installed on the photovoltaic panel 03 in order to change the angle of the photovoltaic panel 03 to follow the move of the incident light source (such as the sun), and further increase the amount of energy generated by incident light 01. However, additional cost to adopt the driver 04 and extra power consumption by the driving itself to construct a solar tracking energy system. As a consequence, to develop a cost effective solar energy system is vital.

### SUMMARY OF THE DISCLOSURE

A light collector comprises a chamber including a first opening, a second opening and a surrounding wall which is configured to surround the first opening and the second opening, wherein the surrounding wall including an inner reflective surface, and the cross sectional area of the first opening is greater than or equal to the cross sectional area of the second opening; and a concentrator disposed on the first opening, wherein the concentrator directs the incoming light into the chamber.

### BRIEF DESCRIPTION OF DRAWINGS

The accompanying drawings are included to provide easy understanding of the application, and are incorporated herein and constitute as part of this specification. The drawings illustrate embodiments of the application and, together with the description, serve to illustrate the principles of the application.

FIG. 1 illustrates a conventional solar cell with tracker.

FIG. 2 illustrates one embodiment of the present disclosure.

FIGS. 3A-3C illustrate embodiments of the present disclosure and incident lights from different directions.

FIGS. 4A-4B illustrate different embodiments of the present disclosure.

FIGS. 5A-5B illustrate different embodiments of the present disclosure.

FIGS. 6A-6B illustrate different embodiments of the present disclosure.

FIG. 7 illustrates an embodiment of the present disclosure.

FIGS. 8A-8B illustrate different embodiments of the present disclosure.

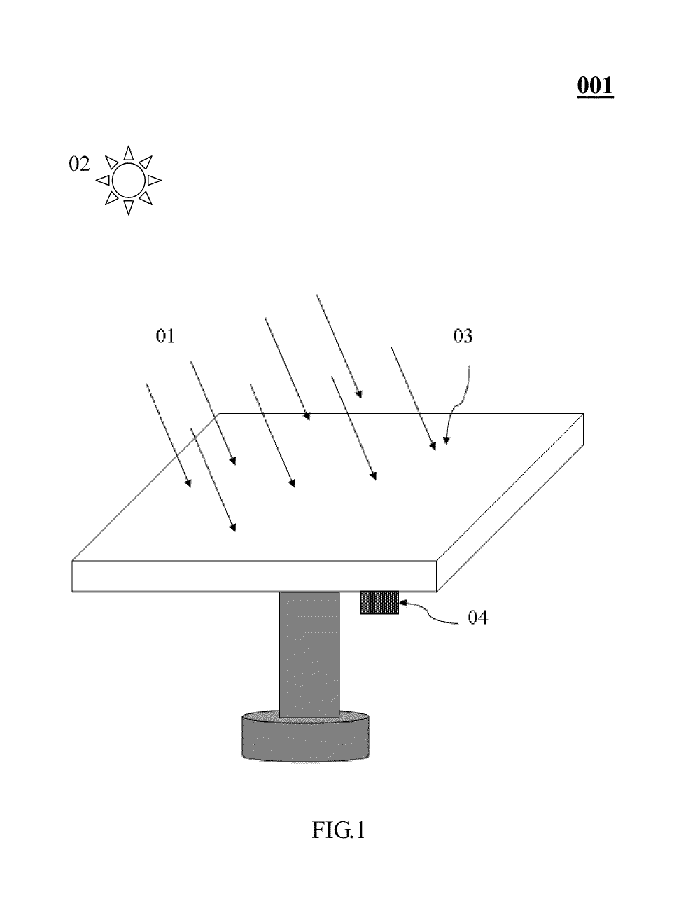

### DETAILED DESCRIPTION OF DISCLOSURE

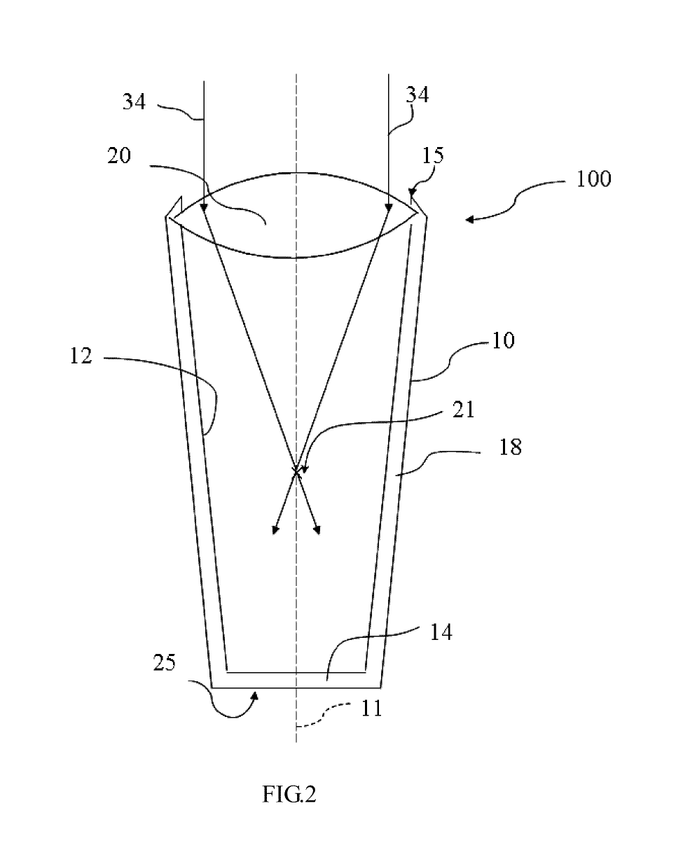

FIG. 2 illustrates one embodiment according to the present disclosure which discloses a multi-directional solar energy collector. The multi-directional solar energy collector includes a first light collector 100 which contains a chamber 10 and a concentrator 20. The chamber 10 includes a surrounding wall 18, a first opening 15 and a second opening 25, and herein the surrounding wall 18 surrounds the first opening 15 and the second opening 25. The cross section area of the first opening 15 is greater than or equal to the area of the second opening 25. In the present embodiment, preferably, the cross section area of the first opening 15 is twice or greater than the area of the second opening 25. The surrounding wall 18 contains an inner reflective surface 12 which is configured to reflect incoming light. The concentrator 20 is located at the first opening 15 and it can be an optical lens, such as a biconvex lens, a positive meniscus lens, a Fresnel lens, a plano convex lens, or a combination of any lens described above. The biconvex lens is selected to represent the concentrator 20 in all embodiments in the present disclosure but there is no restriction to use other different types of lens. As shown in FIG. 2, an incoming light 34 passes through the concentrator 20 and focus on a focal point 21. The chamber 10 further contains an axial line 11, a virtual line propagating the focal point 21 and vertical to a bottom side 14 of the chamber 10.

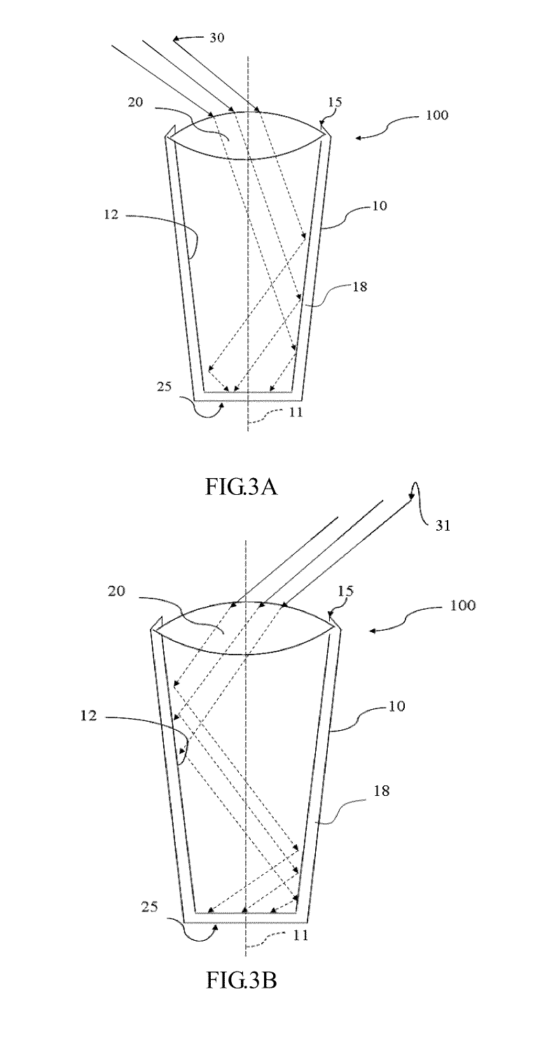

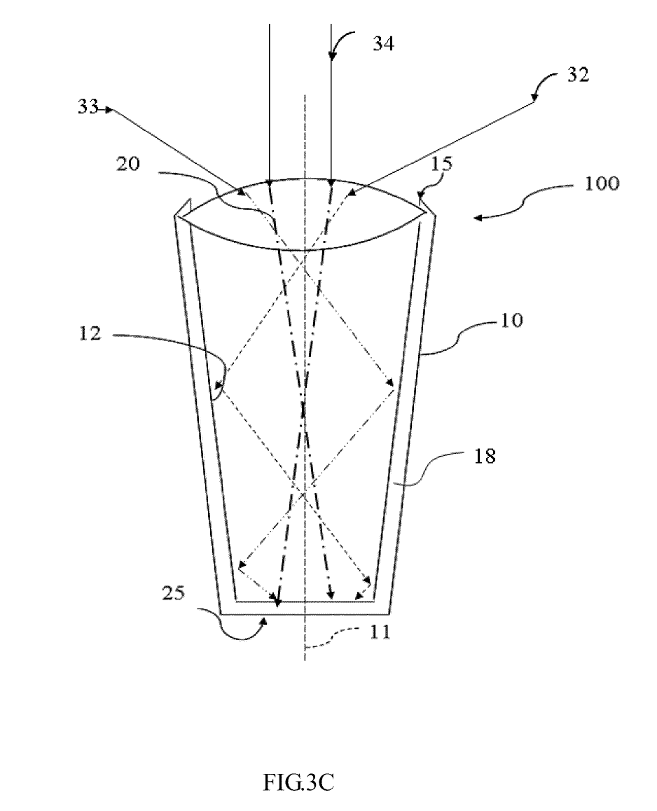

FIG. 3A illustrates a first incoming light 30 passing through the first light collector 100. The first incoming light 30 passes the concentrator 20 and enters into the chamber 10. The first incoming light 30 is refracted by the concentrator 20 and reaches the inner reflective surface 12. After at least one reflection made by the inner reflective surface 12, the first incoming light 30 arrives at the second opening 25. FIG. 3B illustrates a second incoming light 31 having a different incident direction from that of the first incoming light 30. The second incoming light 31 passes the concentrator 20 and enters into the chamber 10. The second incoming light 30 is refracted by the concentrator 20 and reaches the inner reflective surface 12. After at least one reflection made by the inner reflective surface 12, the second incoming light 31 arrives at the second opening 25. FIG. 3C illustrates incoming lights from different incident directions, for example, the three incoming lights 32, 33, and 34 enter the first light collector 100 with different incident angle respectively. Each incoming light passes the concentrator 20 and enters into the chamber 10. The incoming lights 32 and 33 are refracted by the concentrator 20 and reflected at least once by the inner reflective surface 12, and thereafter arrive at the second opening 25. The incoming light 34, instead, arrives at the second opening 25 without any reflection.

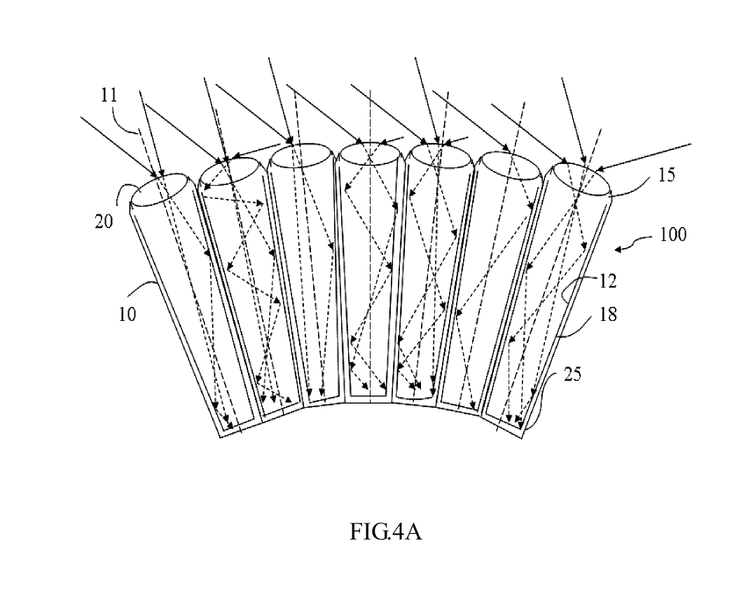

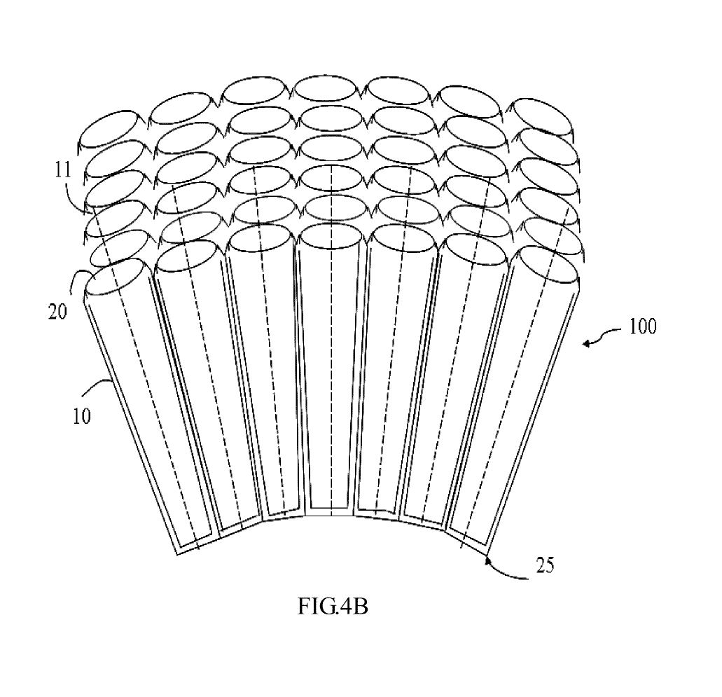

FIG. 4A is another embodiment of the present disclosure and illustrates a plurality of first light collectors 100. Each first light collector 100 includes a chamber 10 with an axial direction 11. The axial direction 11 of each light collector 100 is unparallel to that of its adjacent light collector. The concentrators 20 within the first light collectors 100 form, preferably, an arc, a curvy, or a spheroidal surface. Therefore, incoming lights from different directions enter the plural chambers 10 and reflected by the inner reflective surface 12 of the surrounding wall 18, and finally arrive at the second opening 25. FIG. 4B illustrates another embodiment with a curvy or a spheroidal surface by disposing a plurality of first light collectors 100 in multiple rows to collect more light.

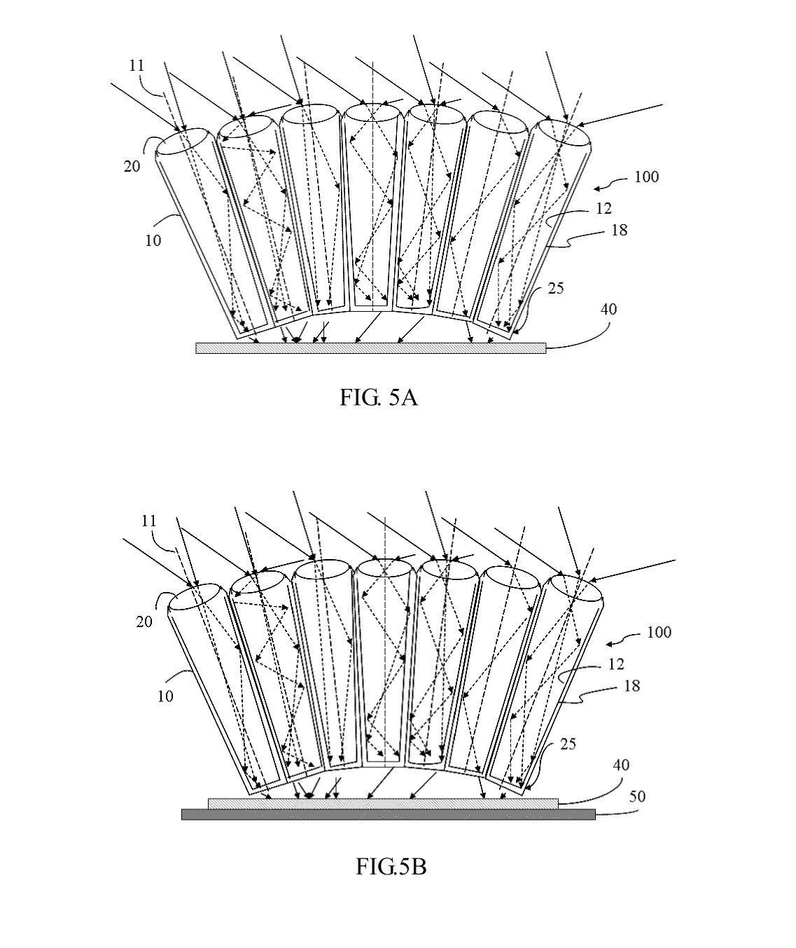

FIG. 5A illustrates another embodiment of the present disclosure including a plurality of first light collectors 100 and a solar cell 40. Each first light collector 100 includes a chamber 10 with an axial direction 11. The axial direction 11 of each first light collector 100 is unparallel to that of its adjacent light collector 100. Examples of the solar cell 40 is composed of single crystal silicon, polycrystalline silicon, amorphous silicon, III-V semiconductor compound, II-VI semiconductor compound, organic photovoltaic material, or combination of the above material. The solar cell 40 is disposed under chambers 10. Incoming lights from various directions enter the plural chambers 10 and reflected by the inner reflective surface 12 of the surrounding wall 18, and finally pass the second opening 25 and arrive at the solar cell 40. Another embodiment as illustrated in FIG. 5B can optionally include a heat dissipation substrate 50 which is disposed under the solar cell 40. Therefore, the heat accumulated in the solar cell 40 can be carried away. This embodiment also can, optionally, expand the plurality of first light collectors 100 to multiple rows as illustrated in FIG. 4B.

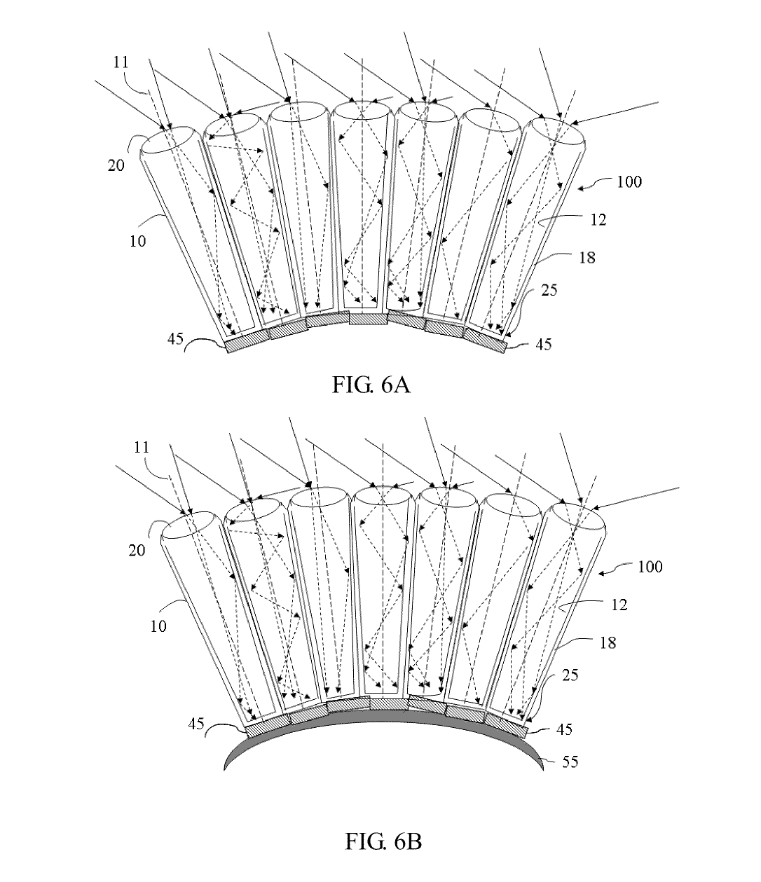

FIG. 6A illustrates another embodiment including a plurality of first light collectors 100 and a plurality of solar cells 45. Each first light collector 100 includes a chamber 10 with an axial direction 11. The axial direction 11 of each first light collector 100 is unparallel to that of its adjacent light collector 100. Each solar cell 45 is disposed under a corresponding second opening 25 and electrically connected with other solar cells 45 in series or parallel mode. Examples of the solar cell 45 is composed of single crystal silicon, polycrystalline silicon, amorphous silicon, III-V semiconductor compound, II-VI semiconductor compound, organic photovoltaic material, or combination of the above material. Incoming light from various directions pass the concentrators 20 and finally arrive at the solar cells 45. FIG. 6B shows an embodiment of the present disclosure that can optionally include a heat dissipation substrate 55 which is disposed under the solar cell 45. Therefore, the heat accumulated in the solar cell 45 can be carried away. This embodiment also can, optionally, expand the plurality of first light collectors 100 to multiple rows as illustrated in FIG. 4B.

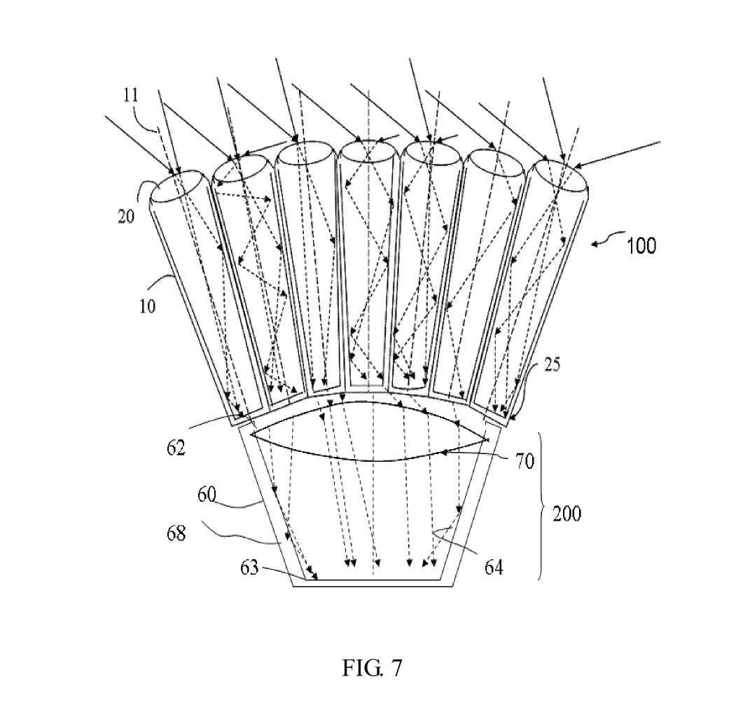

FIG. 7 illustrates another embodiment including a plurality of first light collectors 100 and a plurality of solar cells 45. Each first light collector 100 includes a chamber 10 with an axial direction 11. The axial direction 11 of each first light collector 100 is unparallel to the axial direction 11 of adjacent light collector 100. The embodiment further includes a second light collector 200 which includes a second chamber 60 and a second concentrator 70. The second chamber 60 contains a second surrounding wall 68, a front-end opening 62 and a rear opening 63, wherein the second surrounding wall 68 defines the boundary of the front-end opening 62 and the rear opening 63. The front opening 62 and the rear opening 63 are at the opposite ends of the second chamber 60. The cross-sectional area of the front-end opening 62 is equal to or greater than that of the rear opening 63. In a preferred embodiment according to this disclosure, the cross-sectional area of the front opening 62 is twice or greater than that of the rear opening 63. The second surrounding wall 68 contains a second inner reflective surface 64 which reflects the light. The second concentrator 70 is disposed on the front opening 62, and is an optical lens like a biconvex, positive meniscus lens, Fresnel lens, plano convex or the combination of any prescribed lens. A plurality of first light collectors 100 located on the second light collector 200. Incoming light from various directions enter into a plurality of chambers 10 after passing a plurality of concentrators 20 of the first light collectors 100 and arrive at the front opening 62 of the second light collector 200. Incoming light is further refracted by the second concentrator 70 and guided to the second inner reflective surface 64. The second inner reflective surface 64 is configured to reflect the light at least once; thereto the light arrives at the rear opening 63. Depending on the requirement of the length of second chamber 60, the incoming light may also optionally travel to the rear opening 63 without any reflection by the second inner reflective surface 64. This embodiment also can, optionally, disposing the plurality of first light collectors 100 in multiple rows as illustrated in FIG. 4B.

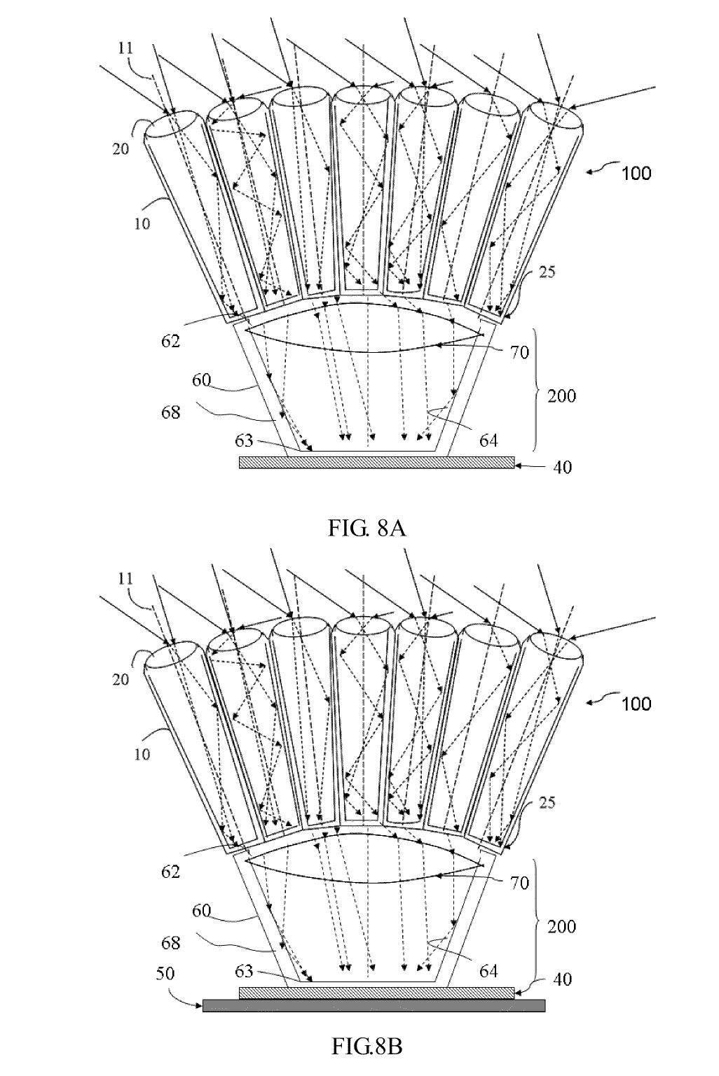

FIG. 8A illustrates another embodiment which includes a plurality of first light collectors 100, a second light collector 200 and a solar cell 40. Each first light collector 100 contains a chamber 10 with an axial direction 11 and the axial direction 11 of each light collector 100 is unparallel to the axial direction 11 of adjacent light collector 100. The second light collector 200 contains a second chamber 60 and a rear opening 63. The solar cell 40 is disposed under the rear opening 63. Incoming light from various directions travel through the first and the second light collectors (100 and 200) and arrive at the solar cell 40. Another embodiment as illustrated in FIG. 8B can optionally include a heat dissipation substrate 50 which is disposed under the solar cell 40. Therefore, the heat accumulated in the solar cell 40 can be carried away. This embodiment also can, optionally, disposing the plurality of first light collectors 100 in multiple rows as illustrated in FIG. 4B.

The foregoing description has been directed to the specific embodiments of this application. It will be apparent; however, that other variations and modifications may be made to the embodiments without escaping the spirit and scope of the application.

What is claimed is:

1. A light collector comprising:
a chamber including a first opening, a second opening, and a surrounding wall surrounding the first opening and the second opening, wherein the surrounding wall including an inner reflective surface, and the cross sectional area of the first opening is greater than or equal to the cross sectional area of the second opening; and
a concentrator disposed on the first opening to direct light into the chamber.

2. The light collector of claim 1, wherein the concentrator is an optical lens selected from the group consisting of a biconvex, a positive meniscus, a Fresnel lens, and a plano convex.

3. The light collector of claim 1, further comprising a solar cell, wherein the solar cell is disposed under the second opening.

4. The light collector of claim 3, further comprising a heat dissipation substrate, wherein the heat dissipation substrate is disposed under the solar cell.

5. The light collector of claim 3, wherein the solar cell is composed of single crystal silicon, polycrystalline silicon, amorphous silicon, III-V semiconductor compound, II-VI semiconductor compound, organic photovoltaic material, or combination of the above material.

6. A multi-directional light collection system comprising:
a plurality of light collectors, wherein each light collector including:
a chamber including a first opening, a second opening, and a surrounding wall surrounding the first opening and the second opening, wherein the surrounding wall including an inner reflective surface, and the cross sectional area of the first opening is greater than or equal to the cross sectional area of the second opening; and
a concentrator disposed on the first opening to direct light into the chamber.

7. The multi-directional light collection system of claim 6, wherein the concentrator is an optical lens selected from the group consisting of a biconvex, a positive meniscus, a Fresnel lens, and a plano convex.

8. The multi-directional light collection system of claim 6, wherein the light collectors form an arc, a curvy, or a spheroidal surface.

9. The multi-directional light collection system of claim 6, further comprising a plurality of solar cells, wherein the solar cells are disposed under the chambers of the light collectors.

10. The multi-directional light collection system of claim 9, further comprising a heat dissipation substrate, wherein the heat dissipation substrate is disposed under the solar cells.

11. The multi-directional light collection system of claim 9, wherein the solar cell is composed of single crystal silicon, polycrystalline silicon, amorphous silicon, III-V semiconductor compound, II-VI semiconductor compound, organic photovoltaic material, or combination of the above material.

12. The multi-directional light collection system of claim 6, further comprising a solar cell, wherein the solar cell is disposed under the chambers of the light collectors.

13. The multi-directional light collection system of claim 12, further comprising a heat dissipation substrate, wherein the heat dissipation substrate is disposed under the solar cell.

14. A multi-directional light collection system comprising:
a plurality of first light collector and each first light collector comprising:
a chamber including a first opening, a second opening, and a surrounding wall surrounding the first opening and the second opening, wherein the surrounding wall including an inner reflective surface, and the cross sectional area of the first opening is greater than or equal to the cross sectional area of the second opening; and
a concentrator disposed on the first opening to direct light into the chamber;
a second light collector comprising:
a second chamber comprising a front opening, a rear opening and a second surrounding wall surrounding the front opening and the rear opening, wherein the second surrounding wall comprising a second inner reflective surface; and
a second concentrator disposed on the front opening to direct light into the second chamber.

15. The multi-directional light collection system of claim 14, wherein the light collectors form an arc, a curvy, or a spheroidal surface.

16. The multi-directional light collection system of claim 14, wherein the concentrator and the second concentrator are optical lens which are configured to concentrate the incoming sunlight, and the concentrator can be a biconvex, a positive meniscus, a Fresnel lens or a plano convex.

17. The multi-directional light collection system of claim 14, further comprising a solar cell, wherein the solar cell is disposed under the second chamber.

18. The multi-directional light collection system of claim 17, further comprising a heat dissipation substrate, wherein the heat dissipation substrate is disposed under the solar cell.

19. The multi-directional light collection system of claim 17, wherein the solar cell is composed of single crystal silicon, polycrystalline silicon, amorphous silicon, III-V semiconductor compound, II-VI semiconductor compound, organic photovoltaic material, or combination of the above material.
